(19) United States
(12) Patent Application Publication
(10) Pub. No.: US 2023/0307528 A1
(43) Pub. Date: Sep. 28, 2023

(54) MANUFACTURING METHOD OF FORMING SEMICONDUCTOR DEVICE AND SEMICONDUCTOR DEVICE

(71) Applicant: PANJIT INTERNATIONAL INC., Kaohsiung (TW)

(72) Inventors: SEUNGCHUL LEE, San Jose, CA (US); SHU-SHU TANG, Hsinchu (TW); CHIH-CHIANG CHUANG, New Taipei (TW)

(21) Appl. No.: 17/705,527

(22) Filed: Mar. 28, 2022

(51) Int. Cl. H01L 29/739; H01L 29/66; H01L 29/06

(52) U.S. Cl. CPC H01L 29/7393; H01L 29/66325; H01L 29/0638

(57) ABSTRACT

A method of forming a semiconductor device and the structure of the semiconductor device are provided. The manufacturing method includes the following steps of: providing a semiconductor substrate with a front side and a back side; forming a collector layer in the back side; conducting a first Hydrogen implant process to the back side to form an N-type region and baking the N-type region with a first annealing temperature to form a field stop buffer layer; conducting a second Hydrogen implant process to the back side to form a lifetime control site and baking the lifetime control site with a second annealing temperature to form a defect layer, wherein the second annealing temperature being lower than the first annealing temperature; and forming a metal layer on the back side.

### BACKGROUND OF THE INVENTION

### 1. Field of the Invention

The present invention generally relates to a manufacturing method of forming a semiconductor device and the structure of the semiconductor device, and in particular, to the semiconductor device containing the local life time controlled area and the manufacturing method of forming the local life time controlled area.

### 2. Description of the Related Art

The insulated gate bipolar transistor (IGBT) device is a semiconductor power device for power conversion. The IGBT device may include a punch-through type insulated gate bipolar transistor (PT-IGBT), a non-punch-through type insulated gate bipolar transistor (NPT-IGBT), or a field-stop type insulated gate bipolar transistor (FS-IGBT). Regarding the FS-IGBT, the field stop layer is formed for stopping the depletion layer, thereby decreasing the turn-on voltage.

The technology used to control switching characteristics of IGBT may provide a big benefit and enable versatility to support various device performance required from several applications. In the conventional technology, the life-time killing processes using the electron irradiation and the Pt diffusion were widely used. However, the cost of the life-time killing process is expensive and the process is complex. The conventional manufacturing process is not suitable for forming the IGBT device.

In summary, the conventional manufacturing method for forming the semiconductor device still has considerable problems. Hence, the present disclosure provides the method of forming the semiconductor device and the structure of the semiconductor device to resolve the shortcomings of conventional technology and promote industrial practicability.

### SUMMARY OF THE INVENTION

In view of the aforementioned technical problems, the primary objective of the present disclosure is to provide a manufacturing method of forming a semiconductor device and the structure of the semiconductor device, which are capable of forming the local life time controlled area by a simple and low cost process.

In accordance with one objective of the present disclosure, a manufacturing method of forming a semiconductor device is provided. The manufacturing method includes the following steps of: providing a semiconductor substrate, the semiconductor substrate including an N-drift layer and the N-drift layer having a front side and a back side; forming a collector layer in the back side by a P-type implant process and conducting an annealing process to the collector layer; conducting a first Hydrogen implant process to the back side to form an N-type region and baking the N-type region with a first annealing temperature to form a field stop buffer layer; conducting a second Hydrogen implant process to the back side to form a lifetime control site and baking the lifetime control site with a second annealing temperature to form a defect layer, the second annealing temperature being lower than the first annealing temperature; forming a metal layer on the back side by a back metallization process.

Preferably, the first annealing temperature may be over 300° C. and the second annealing temperature may be about 100-250° C.

Preferably, the defect layer may be formed in the field stop buffer layer.

Preferably, the defect layer may be formed between the field stop buffer layer and the N-drift layer.

Preferably, the first Hydrogen implant process may implant Hydrogen ions three times to form a first N-type region, a second N-type region and a third N-type region.

Preferably, the defect layer may be formed between the first N-type region and the second N-type region.

Preferably, the defect layer may be formed between the first N-type region and the N-drift layer.

Preferably, the manufacturing method may further include the steps of: etching the front side to form a trench; forming a gate oxide layer on the front side and the gate oxide layer covering surface of the trench; conducting a polysilicon deposition in a trench space and etching back to form a polysilicon layer; implanting the front side to form a P-well region between two trenches; implanting the P-well region to form an N-plus layer within the P-well region; depositing an interlayer dielectric layer to cover the N-plus layer and the polysilicon layer; etching the interlayer dielectric layer to form an opening, the opening passing through the N-plus layer to expose the P-well region; implanting the P-well region through the opening to form a P-plus layer; forming a metal contact layer to cover the opening and the interlayer dielectric layer.

Preferably, the annealing process may be provided after implant process.

In accordance with one objective of the present disclosure, a semiconductor device is provided. The semiconductor device includes a semiconductor substrate, a collector layer, a field stop buffer layer, a defect layer and a metal layer. The semiconductor substrate includes an N-drift layer and the N-drift layer has a front side and a back side. The collector layer is disposed on the back side and the collector layer includes a P-type region. The field stop buffer layer is formed between the N-drift layer and the collector layer. The field stop buffer layer includes an N-type region. The defect layer is formed around boundary of the field stop buffer layer. The metal layer is disposed on the collector layer. Wherein the field stop buffer layer is formed by a first Hydrogen implant process and a baking process at a first annealing temperature, the defect layer is formed by a second Hydrogen implant process and a baking process at a second annealing temperature, the second annealing temperature is lower than the first annealing temperature.

Preferably, the first annealing temperature may be over 300° C. and the second annealing temperature may be about 100-250° C.

Preferably, the defect layer may be disposed in the field stop buffer layer.

Preferably, the defect layer may be disposed between the field stop buffer layer and the N-drift layer.

Preferably, the field stop buffer layer may include a first N-type region, a second N-type region and a third N-type region.

Preferably, the defect layer may be disposed between the first N-type region and the second N-type region.

Preferably, the defect layer may be disposed between the first N-type region and the N-drift layer.

Preferably, the semiconductor device may further include a gate oxide layer, a polysilicon layer, a P-well region, a P-plus layer, an N-plus layer, an interlayer dielectric layer and a metal contact. The gate oxide layer is disposed on a trench of the front side. The polysilicon layer is disposed on the gate oxide layer, and the polysilicon layer fills in a trench space. The P-well region is disposed between two trenches. The P-plus layer and the N-plus layer are disposed within the P-well region, and the N-plus layer is disposed on the P-plus layer. The interlayer dielectric layer is disposed on the polysilicon layer and the N-plus layer. The metal contact layer is disposed on the interlayer dielectric layer and the metal contact layer reaches the P-plus layer and the N-plus layer through an opening of the interlayer dielectric layer.

As mentioned previously, the method of forming the semiconductor device and the structure of the semiconductor device in accordance with the present disclosure may have one or more advantages as follows.

1. The method of forming the semiconductor device and the structure of the semiconductor device are capable of increasing the switching performance controllability of the semiconductor device by adoption of the local life-time control site formed near the field stop layer.

2. The method of forming the semiconductor device and the structure of the semiconductor device may enable faster switching speed of the semiconductor device based on the local life-time control site formed near the field stop layer.

3. The method of forming the semiconductor device and the structure of the semiconductor device may form the local life-time control site by the same oxidation process with only different annealing temperatures. The cost of the manufacturing process and the process variation can be reduced.

### BRIEF DESCRIPTION OF THE DRAWINGS

The technical features, detail structures, advantages and effects of the present disclosure will be described in more details hereinafter with reference to the accompanying drawings that show various embodiments of the invention as follows.

FIG. 1A and FIG. 1B are schematic diagrams of the power semiconductor device in accordance with the embodiment of the present disclosure.

FIG. 2A to FIG. 2E are schematic diagrams of the manufacturing process of forming the power semiconductor device in accordance with the embodiment of the present disclosure.

FIG. 3A to FIG. 3H are schematic diagrams of the manufacturing process of forming the front side of the power semiconductor device in accordance with the embodiment of the present disclosure.

FIG. 4A to FIG. 4E are schematic diagrams of the manufacturing process of forming the power semiconductor device in accordance with another embodiment of the present disclosure.

### DETAILED DESCRIPTION OF THE PREFERRED EMBODIMENTS

In order to facilitate the understanding of the technical features, the contents and the advantages of the present disclosure, and the effectiveness thereof that can be achieved, the present disclosure will be illustrated in detail below through embodiments with reference to the accompanying drawings. The diagrams used herein are merely intended to be schematic and auxiliary to the specification, but are not necessary to be true scale and precise to the configuration after implementing the present disclosure. Thus, it should not be interpreted in accordance with the scale and the configuration of the accompanying drawings to limit the scope of the present disclosure on the practical implementation.

As those skilled in the art would realize, the described embodiments may be modified in various different ways. The exemplary embodiments of the present disclosure are for explanation and understanding only. The drawings and description are to be regarded as illustrative in nature and not restrictive. Similar reference numerals designate similar elements throughout the specification.

It is to be acknowledged that, although the terms ‘first’, ‘second’, ‘third’, and so on, may be used herein to describe various elements, these elements should not be limited by these terms.

These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

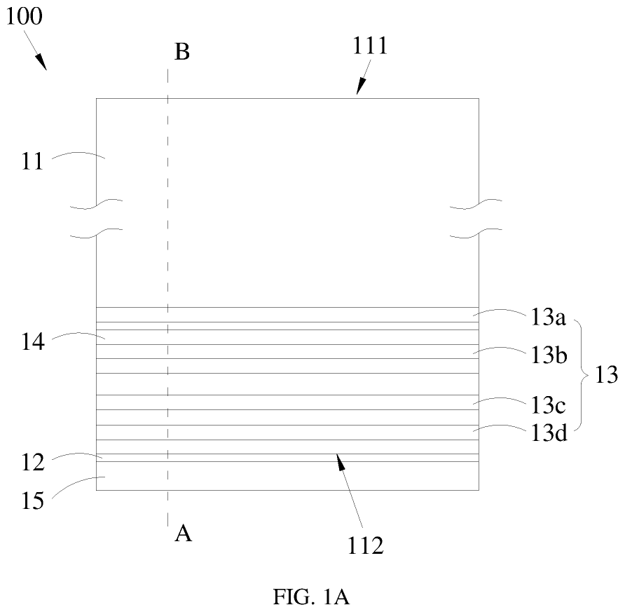

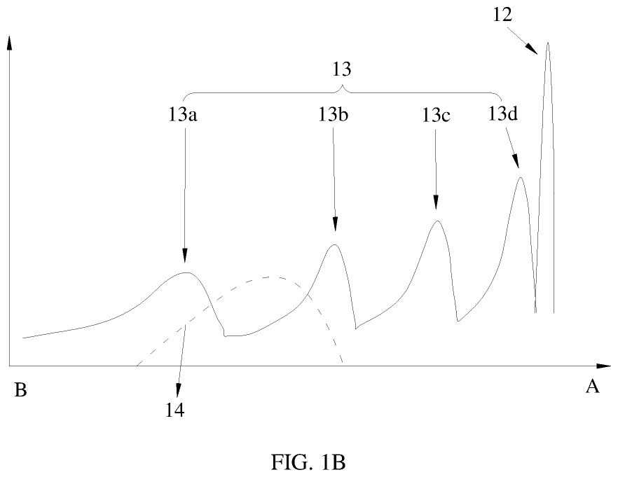

Please refer to FIG. 1A and FIG. 1B, which are schematic diagrams of the power semiconductor device in accordance with the embodiment of the present disclosure. FIG. 1A shows the section view of a power semiconductor device 100. FIG. 1B shows the schematic diagram of the doping concentration along the dash line AB of the FIG. 1A.

As shown in FIG. 1A, the semiconductor device 100 includes a semiconductor substrate 11, a collector layer 12, a field stop buffer layer 13, a defect layer 14 and a metal layer 15. The semiconductor device 100 may be an insulated gate bipolar transistor (IGBT). The semiconductor substrate 11 may be an N-drift layer and the N-drift layer has a front side 111 and a back side 112. The collector layer 12 is disposed on the back side 112 of the N-drift layer. The collector layer 12 is a P-type region formed by a P-type implant process. An annealing process can be conducted after the implant process. After forming the collector layer 12, the first Hydrogen implant process is conducted to the back side 112 to form the field stop buffer layer 13. The annealing process can be conducted after the first Hydrogen implant process. The field stop buffer layer 13 is disposed between the N-drift layer of the semiconductor substrate 11 and the collector layer 12. The field stop buffer layer 13 is an N-type region and can be a multilayer structure with different doping concentration layers. In the present disclosure, the field stop buffer layer 13 includes four N-type regions. That is, the first n-type region 13a, the second n-type region 13b, the third n-type region 13c and the fourth n-type region 13d. The numbers of the n-type regions can be changed according to the numbers of the ions implant.

After the first time of the Hydrogen ions implant, the first n-type region 13a is formed at the deepest position of the N-drift layer. With the second, the third and the fourth Hydrogen ions implants, second n-type region 13b, the third n-type region 13c and the fourth n-type region 13d are sequentially formed at the N-drift layer. As shown in FIG. 1A, the fourth n-type region 13d is closest to the back side 112 and the first n-type region 13a is farthest from the back side 112. The depth and the ions concentration of each region are different and can be controlled by the implant energy used in the implant processes and the baking temperature used after the implant process. Please also refer to FIG. 1B, the dash line AB shows the section view of the depth location in the semiconductor structure. The fourth n-type region 13d is closest to the collector layer 12 and the first n-type region 13a is farthest from the collector layer 12. The fourth n-type region 13d has the highest ion doping concentration and the first n-type region 13a has the lowest ion doping concentration.

The first n-type region 13a, the second n-type region 13b, the third n-type region 13c and the fourth n-type region 13d form the field stop buffer layer 13 of the IGBT. The IGBT devices are required to support different switching characteristics according to applications, therefore a good controllability of the IGBT switching performance is a certainly necessary technology for the semiconductor device 100. Since the recombination of the hole carrier near the field stop layer 13 dominantly determines the switching characteristics, the defect layer 14 is formed around the field stop buffer layer 13 to provide good flexibility on switching performance control in addition to the field stop layer design. The defect layer 14 is effective to improve the switching speed of the IGBT because the accelerating recombination of the injected hole is made by the local life-time control site during switching operation. Therefore, the IGBT device may have the faster switching speed.

In the present disclosure, a second Hydrogen implant process is conducted to form a lifetime control site and the baking process is conducted to the lifetime control site to form the defect layer 14. The defect layer 14 is disposed around boundary of the field stop buffer layer 13. As shown in FIG. 1A and FIG. 1B, the defect layer 14 is disposed between the first n-type region 13a and the second n-type region 13b. However, the present disclosure is not limited to this. In other embodiments, the defect layer 14 may be formed between the field stop buffer layer 13 and the N-drift layer. The field stop buffer layer 13 is formed by the first Hydrogen implant process and the baking process after the first Hydrogen implant process is at a first annealing temperature. The defect layer 14 is formed by a second Hydrogen implant process and the baking process after the second Hydrogen implant process at a second annealing temperature, the second annealing temperature is lower than the first annealing temperature. In the present disclosure, the first annealing temperature may be over 300° C. and the second annealing temperature may be about 100-250° C. After forming the defect layer 14, the metal layer 15 is formed on the collector layer 12 by a back metallization process.

Based on the present disclosure, the local lifetime control site and the buffer layer can be made by the similar Hydrogen implant process. The only different is the annealing temperature. Accordingly, the field stop buffer layer 13 and the defect layer 14 can be formed by the same process with only the different annealing temperature. The manufacturing process can be simplified to reduce the manufacturing costs. The above description illustrates the back side structure of the semiconductor device 100. The detail manufacturing process to the above structure will be illustrated in the following embodiments.

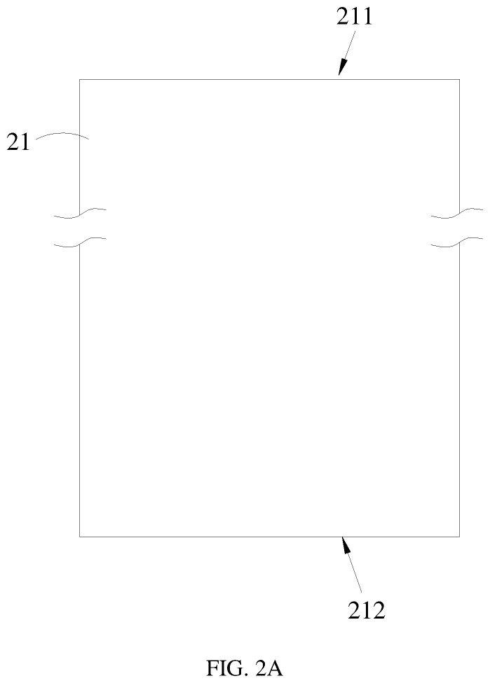

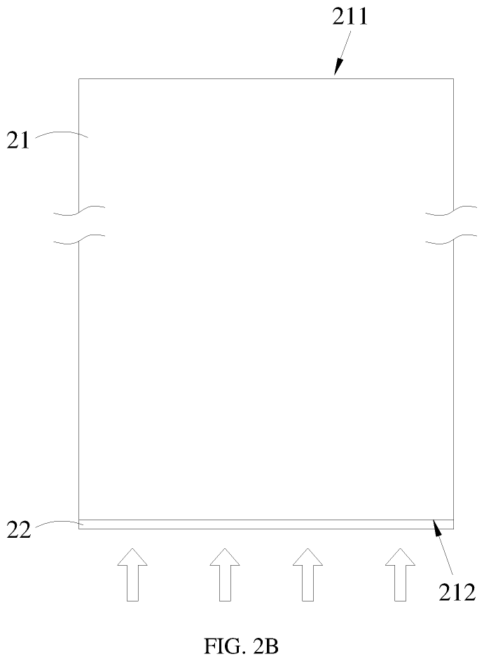

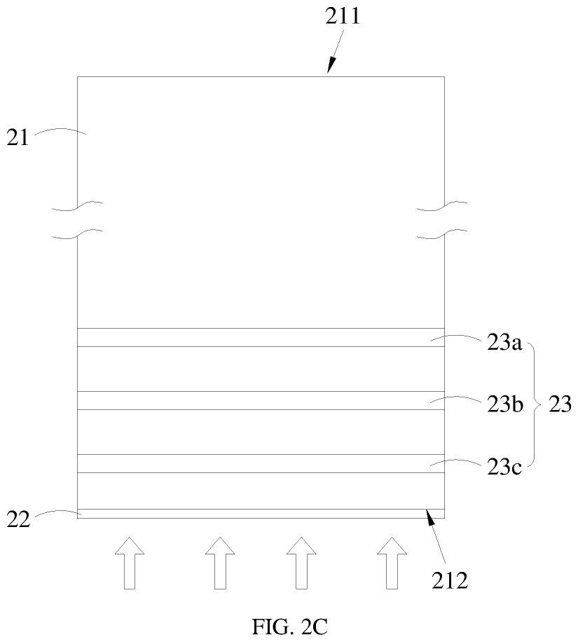

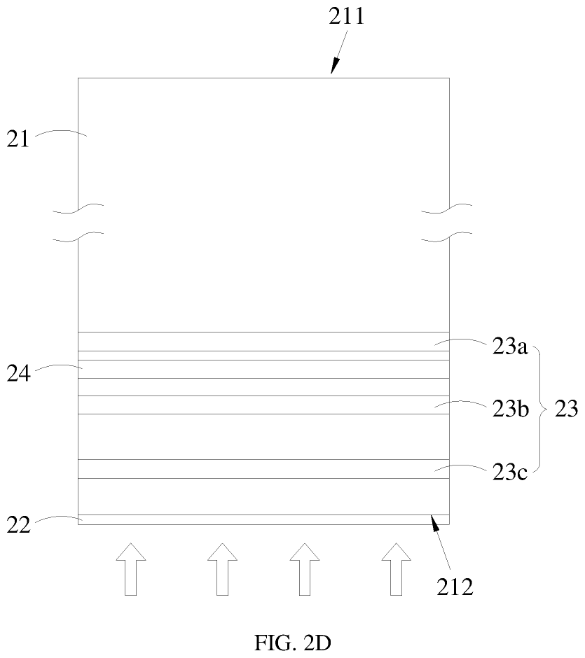

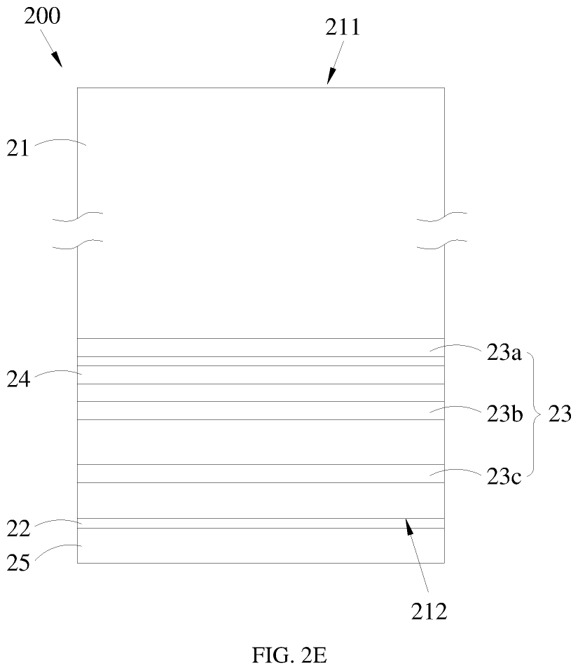

Please refer to FIG. 2A to FIG. 2E, which are the schematic diagrams of the manufacturing process of forming the power semiconductor device in accordance with the embodiment of the present disclosure.

In FIG. 2A, the manufacturing process provides a semiconductor substrate 21, the semiconductor substrate may be an N-drift layer and the N-drift layer has a front side 211 and a back side 212. The manufacturing process provides a semiconductor layer and the semiconductor layer has a first conductivity type, for example, an N-type lightly doped layer.

In FIG. 2B, the manufacturing process forms a collector layer 22 in the back side 212 by a P-type implant process and conducting an annealing process to the collector layer 22. A predetermined dose amount of boron is implanted with predetermined energy toward the back side 212. Then the annealing process is conducted to bake the back side 212 at a predetermined temperature. In this step, the annealing temperature is not limited in specific range. The annealing temperature is sufficient to activate the boron ions. Thus, the collector layer 22, for example a P-plus layer, is formed on the back side 212 of the semiconductor substrate 21.

In FIG. 2C, the manufacturing process conducts a first Hydrogen implant process to the back side 212 to form a N-type region and baking the N-type region with a first annealing temperature to form a field stop buffer layer 23. After forming the collector layer 22, a predetermined dose amount of Hydrogen is implanted with predetermined energy toward the back side 212. The Hydrogen ions can pass the collector layer 22 because of the smallest atomic radius. The N-type region is formed adjacent to the collector layer 22. Then the annealing process is conducted to bake the back side 212 at the first annealing temperature. The field stop buffer layer 23, for example an N-plus layer, is formed within the semiconductor substrate 21.

In the present disclosure, the first Hydrogen implant process may implant Hydrogen ions three times to form a first N-type region 23a, a second N-type region 23b and a third N-type region 23c. The third N-type region 23c is closest to the collector layer 22. These three regions are baked at the first annealing temperature for forming the field stop buffer layer 23. Similar to the previous embodiment, the numbers of the N-type regions are not limited by the present disclosure. The depth and the ions concentration of each region are different and can be controlled by the implant energy used in the implant processes and the baking temperature used after the implant process. The third N-type region 23c may have the highest ion doping concentration and the first n-type region 23a may have the lowest ion doping concentration.

In FIG. 2D, the manufacturing process conducts a second Hydrogen implant process to the back side 212 to form a lifetime control site and baking the lifetime control site with a second annealing temperature to form a defect layer 24. After forming the field stop buffer layer 23, the predetermined dose amount of Hydrogen is implanted with predetermined energy toward the back side 212 again to form the lifetime control site. Then the annealing process is conducted to bake the back side 212 at the second annealing temperature. The different from the previous step is that the second annealing temperature is lower than the first annealing temperature. For example, the first annealing temperature may be over 300° C. and the second annealing temperature may be about 100-250° C.

The defect layer 24 is formed around boundary of the field stop buffer layer 23. In the present disclosure, the defect layer 24 is disposed in the field stop buffer layer 23. That is, between the first N-type region 23a and the second N-type region 23b. However, the present disclosure is not limited in this. In other embodiment, the defect layer 24 may be formed between the first N-type region 23a and the N-drift layer of the semiconductor substrate 21. The controllability of the switching performance for the semiconductor device can be obtained by disposing the defect layer 24. Therefore, the switching performance can be controlled and may have the good flexibility. In addition, the field stop buffer layer 23 and the defect layer 24 can be formed by the same Hydrogen implant process with only the different annealing temperature. The manufacturing process can be simplified to reduce the manufacturing costs.

In FIG. 2E, the manufacturing process forms a metal layer 25 on the back side 212 by a back metallization process. The metal layer 25 is disposed on the collector layer 22 for forming the collector electrode. The metal layer 25 may include conductive materials like Aluminum (Al), Chrome (Cr), Copper (Cu), Nickel (Ni), Gold (Au) and so on. The back metallization process may include metal deposition, sputtering or other metal film forming process.

As shown in FIG. 2E, A semiconductor device 200 is provided. The semiconductor device 200 includes the semiconductor substrate 21, the collector layer 22, the field stop buffer layer 23, the defect layer 24 and a metal layer 25. The semiconductor substrate 21 includes the N-drift layer and the N-drift layer has the front side 211 and the back side 212. The collector layer 22 is disposed on the back side 212 and the collector layer 22 includes the P-type region. The field stop buffer layer 23 is formed between the N-drift layer of the semiconductor substrate 21 and the collector layer 22. The field stop buffer layer 23 includes the N-type region. The defect layer 24 is formed around boundary of the field stop buffer layer 23. The metal layer 25 is disposed on the collector layer 22. The collector layer 23 is formed by the first Hydrogen implant process and the baking process at the first annealing temperature. In the present disclosure, the field stop buffer layer 23 includes the first N-type region 23a, the second N-type region 23b and the third N-type region 23c.

The defect layer 24 is formed by the second Hydrogen implant process and the baking process at the second annealing temperature, the second annealing temperature is lower than the first annealing temperature. The first annealing temperature may be over 300° C. and the second annealing temperature may be about 100-250° C.

In the present disclosure, the defect layer 24 is disposed in the field stop buffer layer 23. That is, the defect layer 24 is disposed between the first N-type region 23a and the second N-type region 23b. However, the position of the defect layer 24 is not limited by the present embodiment. In other embodiments, the defect layer 24 may be disposed between the first N-type region 23a and the N-drift layer of the semiconductor substrate 21.

The above embodiments show the manufacturing process to the back side 212 of the semiconductor device 200. The following embodiment will further illustrate the manufacturing process to the front side 211 of the semiconductor device 200.

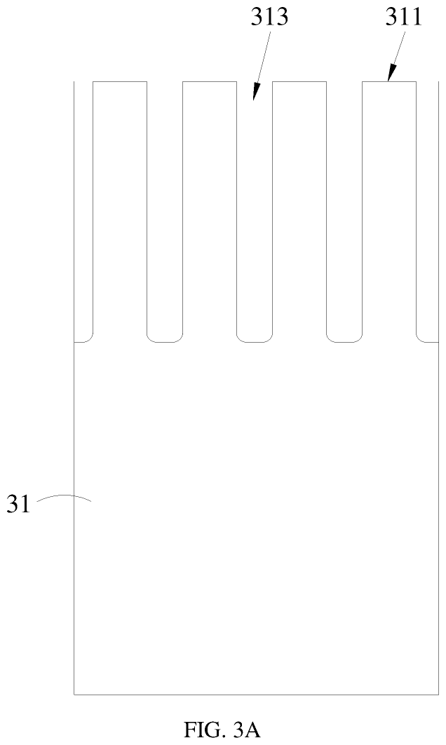

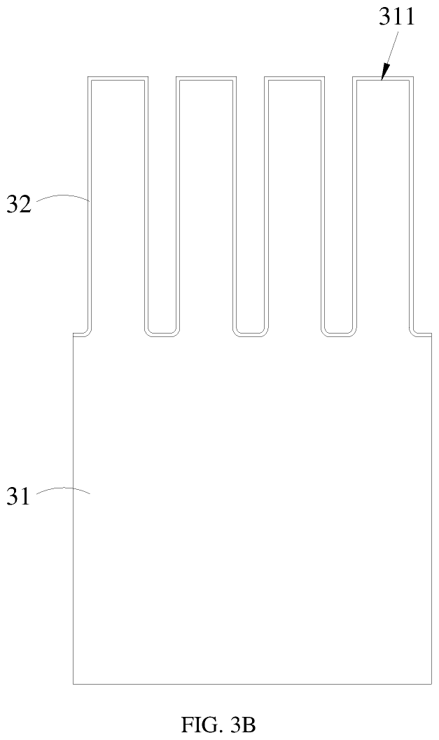

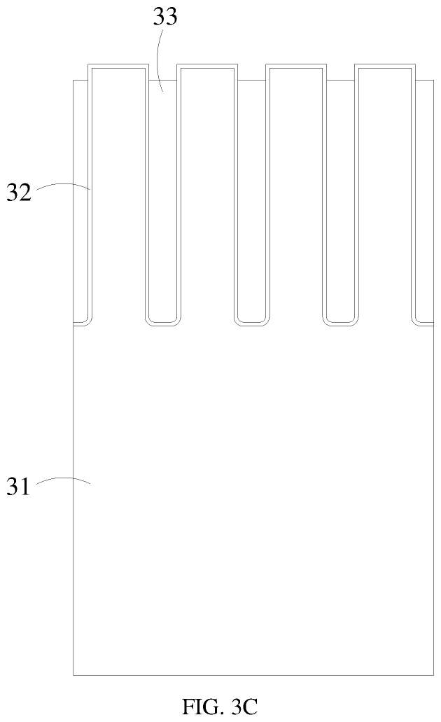

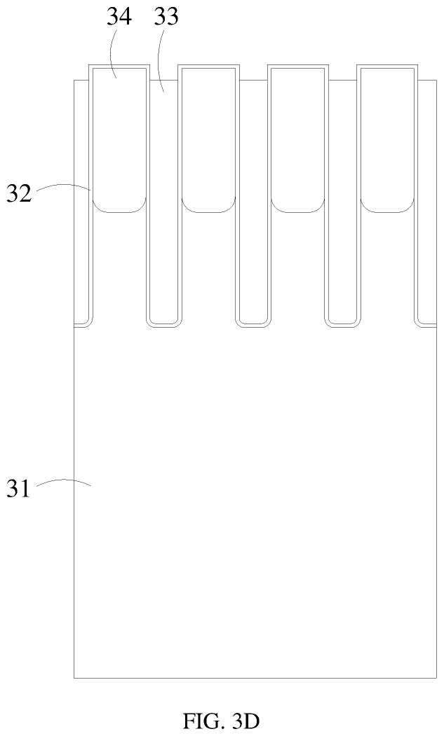

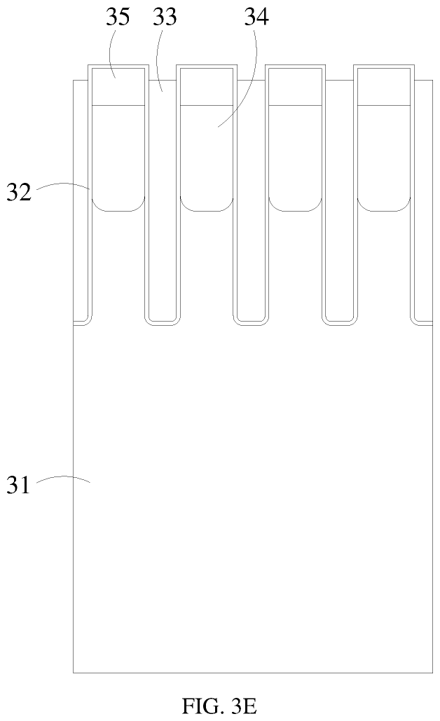

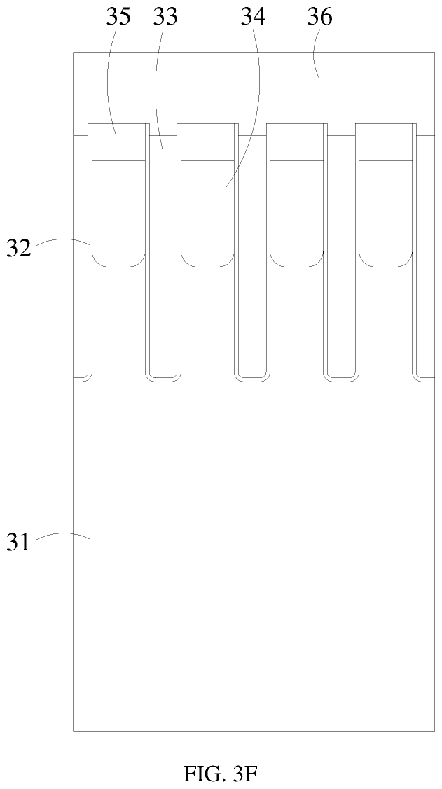

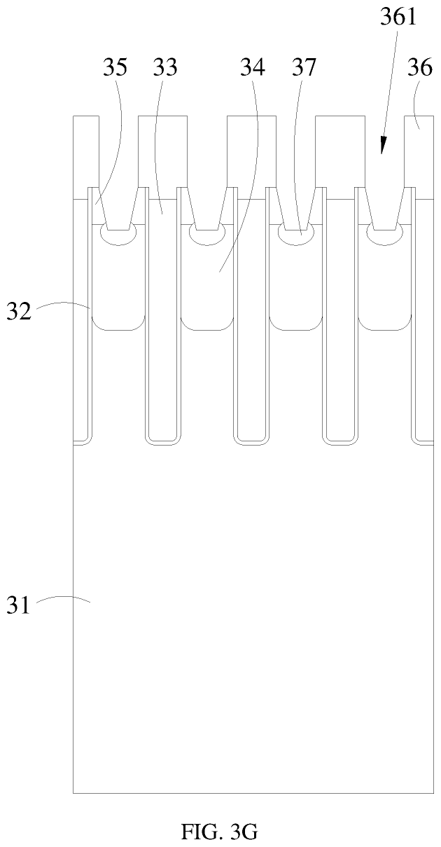

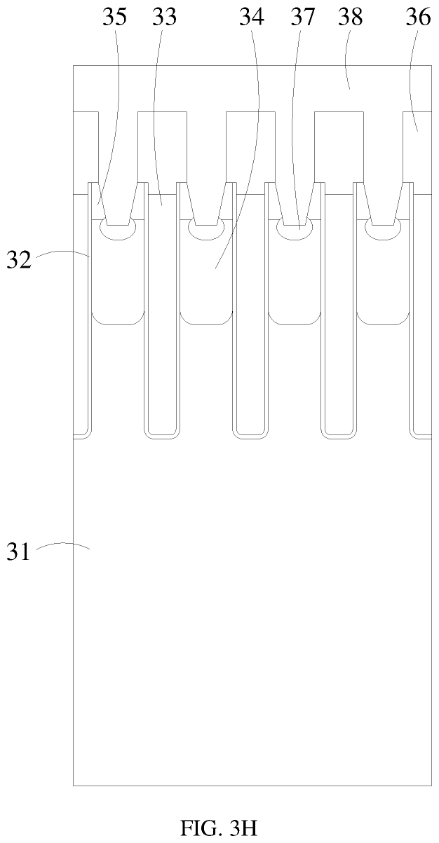

Please refer to FIG. 3A to FIG. 3H, which are the schematic diagrams of the manufacturing process of forming the front side of the power semiconductor device in accordance with the embodiment of the present disclosure.

In FIG. 3A, the manufacturing process provides a semiconductor substrate 31 and etches the front side 311 to form a trench 313. The semiconductor substrate 31 can be the same to the previous embodiment. The semiconductor substrate 31 may be an N-drift layer and the N-drift layer has a front side 311. The manufacturing process provides the semiconductor substrate 31 with a first conductivity type, for example, an N-type lightly doped layer. In this step, the hard mask can be used to define the trench position and the etching process is conducted to form the trench 313. The numbers of the trench 313 can be more than one and the multiple trenches 313 are determined by the type of the semiconductor device.

In FIG. 3B, the manufacturing process forms a gate oxide layer 32 on the front side 311 and the gate oxide layer 32 covering surface of the trench 313. In this step, the gate oxide layer 32 is deposited on the surface of the front side 311 and the surface of the trench 313. The gate oxide layer 32 may include silicon dioxide or other dielectric material. An oxidation process and an anneal process can be used to form the gate oxide layer 32 on the surface of the semiconductor substrate 31.

In FIG. 3C, the manufacturing process conducts a polysilicon deposition in a trench space and etching back to form a polysilicon layer 33. In this step, the polysilicon material is deposited and filled in the trench 313. The part of the polysilicon is etched back to define the polysilicon layer 33.

In FIG. 3D, the manufacturing process implanting the front side 311 to form a P-well region 34 between two trenches. In this step, the polysilicon layer 33 is used as the P-well mask and the N-drift layer of the semiconductor substrate 31 is implanted by the dopants to form the P-well region 34. The P-well region 34 is baked by an annealing process. The P-well region 34 is disposed at the position between the two trenches 313.

In FIG. 3E, the manufacturing process implants the P-well region 34 to form an N-plus layer 35 within the P-well region 34. In this step, the P-well region 34 is implanted by the N-type ions to form the N-Plus region. The N-Plus region is baked by the annealing process to form the N-plus layer 35. The N-plus layer 35 is disposed within the P-well region 34 and is adjacent to the top side of the P-well region 34.

In FIG. 3F, the manufacturing process deposits an interlayer dielectric layer 36 to cover the N-plus layer 35 and the polysilicon layer 33. In this step, the interlayer dielectric layer 36 is formed by the dielectric material deposition. The dielectric material may include oxide dielectric material or nitride dielectric material, like silicon oxide or silicon nitride. The interlayer dielectric layer 36 covers the front side 311. That is, the N-plus layer 35 and the polysilicon layer 33 are fully covered by the interlayer dielectric layer 36.

In FIG. 3G, the manufacturing process etches the interlayer dielectric layer 36 to form an opening 361, the opening 361 passing through the N-plus layer 35 to expose the P-well region 34. The manufacturing process further implants the P-well region 34 through the opening 361 to form a P-plus layer 37. In order to form the P-plus region 34, the interlayer dielectric layer 36 is etched to form the opening 361. The position of the opening 361 corresponds to the location of the N-plus layer 35. The depth of the opening 361 is enough to pass through the N-plus layer 35 and the P-well region 34 is exposed by the opening 361. Since the P-well region 34 is exposed, P-well region 34 can be implanted by the P-type ions to form the P-Plus region. The P-Plus region is baked by the annealing process to form the P-plus layer 37. The P-plus layer 35 is disposed within the P-well region 34 and is adjacent to the top side of the P-well region 34.

In FIG. 3H, the manufacturing process forms a metal contact layer 38 to cover the opening 361 and the interlayer dielectric layer 36. According to the previous step, the opening 361 may expose both the N-plus layer 35 and the P-plus layer 37. The metal contact layer 38 is disposed on the front side 311 for forming the contact electrode. The metal contact layer 38 fills in the opening 361 and covers the interlayer dielectric layer 36. The metal contact layer 38 reaches both the N-plus layer 35 and the P-plus layer 37. The metal contact layer 38 may include conductive materials like Aluminum (Al), Chrome (Cr), Copper (Cu), Nickel (Ni), Gold (Au) and so on. The metal contact layer 38 can be formed by metal deposition, sputtering or other metal film forming process.

As shown in FIG. 3H, the front side 311 of the semiconductor device may include the gate oxide layer 32, the polysilicon layer 33, the P-well region 34, the P-plus layer 37, the N-plus layer 35, the interlayer dielectric layer 36 and the metal contact layer 38. The gate oxide layer 32 is disposed on the trench 313 of the front side 311. The polysilicon layer 33 is disposed on the gate oxide layer 32, and the polysilicon layer 33 fills in the trench space. The P-well region 34 is disposed between two trenches 313. The P-plus layer 37 and the N-plus layer 35 are disposed within the P-well region 34, and the N-plus layer 35 is disposed on the P-plus layer 37. The interlayer dielectric layer 36 is disposed on the polysilicon layer 33 and the N-plus layer 35. The metal contact layer 38 is disposed on the interlayer dielectric layer 36 and the metal contact layer 38 reaches the P-plus layer 37 and the N-plus layer 35 through the opening 361 of the interlayer dielectric layer 36.

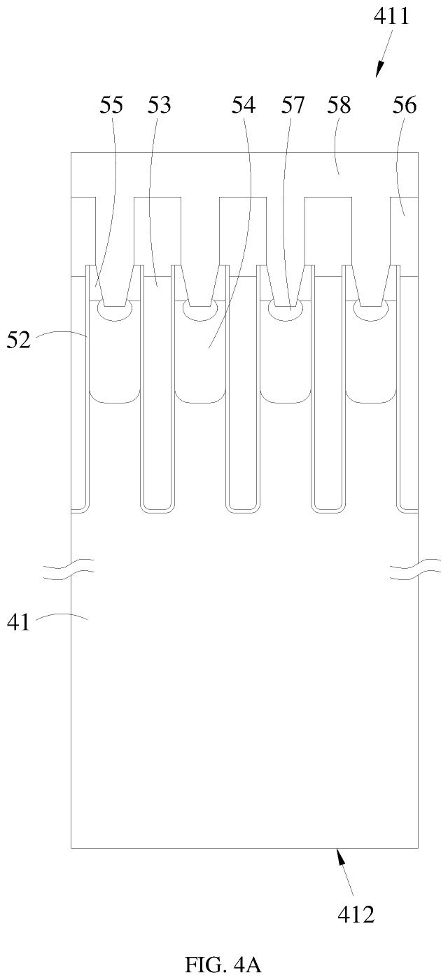

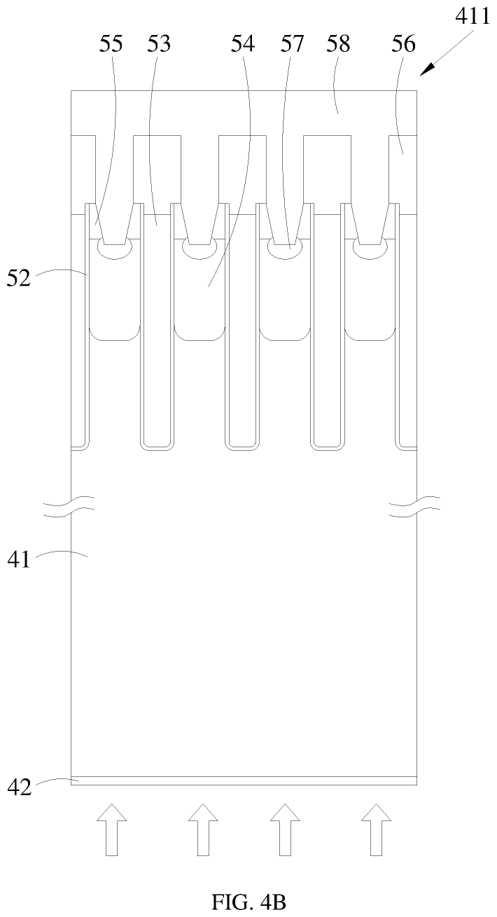

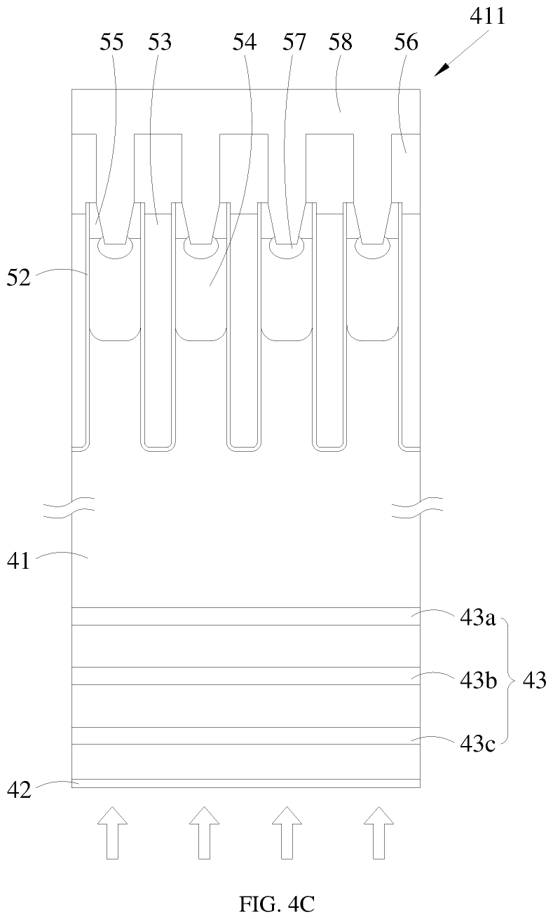

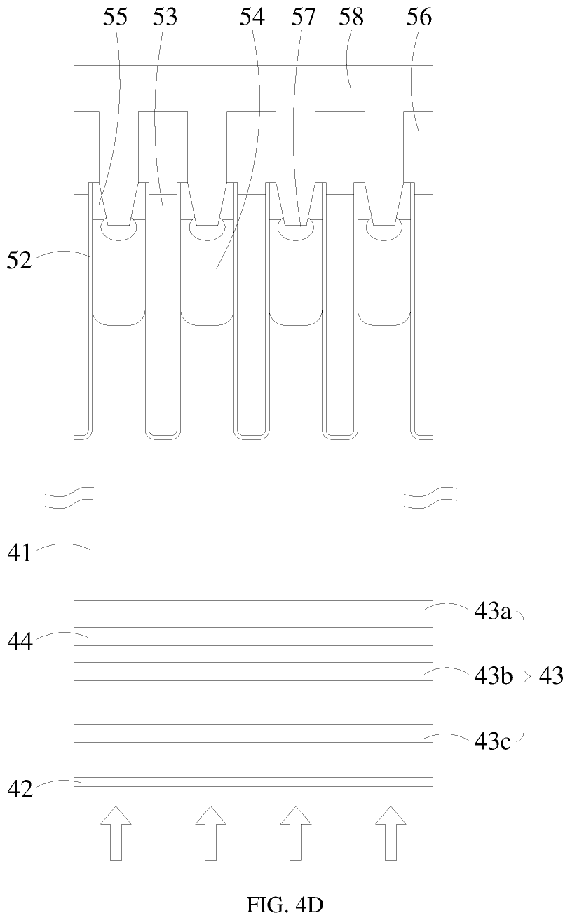

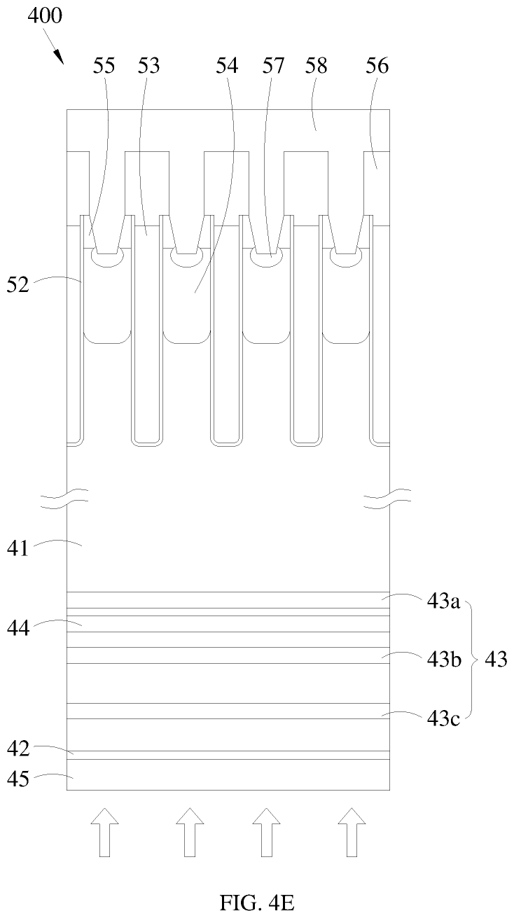

Please refer to FIG. 4A to FIG. 4E, which are the schematic diagrams of the manufacturing process of forming the power semiconductor device in accordance with another embodiment of the present disclosure. The manufacturing process may also include the process described in FIG. 3A to FIG. 3H, the similar numeral numbers refer the similar elements and the same content will not be repeated again.

In FIG. 4A, the manufacturing process provides a semiconductor substrate 41, the semiconductor substrate may be an N-drift layer and the N-drift layer has a front side 411 and a back side 412. The manufacturing process provides a semiconductor layer and the semiconductor layer has a first conductivity type, for example, an N-type lightly doped layer.

In the present disclosure, the manufacturing process to the front side 411 is conducted before the manufacturing process to the back side 412. The structure of the However, in the other embodiment, the manufacturing process to the front side 411 can be conducted after the manufacturing process to the back side 412.

The preprocessing steps to the front side 411 may refer to the steps described in the previous embodiment. That is, the manufacturing process provides a semiconductor substrate 41 and etches the front side 411 to form the trench. The gate oxide layer 52 is formed on the front side 411 and the gate oxide layer 52 covering surface of the trench. The polysilicon deposition is conducted in a trench space and etching back to form the polysilicon layer 53. The front side 411 is implanted to form the P-well region 54 between two trenches. The P-well region 54 is implanted to form the N-plus layer 55 within the P-well region 54. The interlayer dielectric layer 56 is deposited to cover the N-plus layer 55 and the polysilicon layer 53. The interlayer dielectric layer 56 is etched to form the opening passing through the N-plus layer 55 to expose the P-well region 54. The P-well region 54 is implanted through the opening to form the P-plus layer 57. The metal contact layer 58 is formed to cover the opening and the interlayer dielectric layer 56.

In FIG. 4B, the manufacturing process forms a collector layer 42 in the back side 412 by a P-type implant process and conducting an annealing process to the collector layer 42. A predetermined dose amount of boron is implanted with predetermined energy toward the back side 412. Then the annealing process is conducted to bake the back side 412 at a predetermined temperature. In this step, the annealing temperature is not limited in specific range. The annealing temperature is sufficient to activate the boron ions. Thus, the collector layer 42, for example a P-plus layer, is formed on the back side 412 of the semiconductor substrate 41.

In FIG. 4C, the manufacturing process conducts a first Hydrogen implant process to the back side 412 to form a N-type region and baking the N-type region with a first annealing temperature to form a field stop buffer layer 43. After forming the collector layer 42, a predetermined dose amount of Hydrogen is implanted with predetermined energy toward the back side 412. The Hydrogen ions can pass the collector layer 42 because of the smallest atomic radius. The N-type region is formed adjacent to the collector layer 42. Then the annealing process is conducted to bake the back side 412 at the first annealing temperature. The field stop buffer layer 43, for example an N-plus layer, is formed within the semiconductor substrate 41.

In the present disclosure, the first Hydrogen implant process may implant Hydrogen ions three times to form a first N-type region 43a, a second N-type region 43b and a third N-type region 43c. The third N-type region 43c is closest to the collector layer 42. These three regions are baked at the first annealing temperature for forming the field stop buffer layer 43. Similar to the previous embodiment, the numbers of the N-type regions are not limited by the present disclosure. The depth and the ions concentration of each region are different and can be controlled by the implant energy used in the implant processes and the baking temperature used after the implant process. The third N-type region 43c may have the highest ion doping concentration and the first n-type region 43a may have the lowest ion doping concentration.

In FIG. 4D, the manufacturing process conducts a second Hydrogen implant process to the back side 412 to form a lifetime control site and baking the lifetime control site with a second annealing temperature to form a defect layer 44. After forming the field stop buffer layer 43, the predetermined dose amount of Hydrogen is implanted with predetermined energy toward the back side 412 again to form the lifetime control site. Then the annealing process is conducted to bake the back side 412 at the second annealing temperature. The different from the previous step is that the second annealing temperature is lower than the first annealing temperature. For example, the first annealing temperature may be over 300° C. and the second annealing temperature may be about 100-250° C.

The defect layer 44 is formed around boundary of the field stop buffer layer 43. In the present disclosure, the defect layer 44 is disposed in the field stop buffer layer 43. That is, between the first N-type region 43a and the second N-type region 43b. However, the present disclosure is not limited in this. In other embodiment, the defect layer 44 may be formed between the first N-type region 43a and the N-drift layer of the semiconductor substrate 41. The controllability of the switching performance for the semiconductor device can be obtained by disposing the defect layer 44. Therefore, the switching performance can be controlled and may have the good flexibility. In addition, the field stop buffer layer 43 and the defect layer 44 can be formed by the same Hydrogen implant process with only the different annealing temperature. The manufacturing process can be simplified to reduce the manufacturing costs.

In FIG. 4E, the manufacturing process forms a metal layer 45 on the back side 412 by a back metallization process. The metal layer 45 is disposed on the collector layer 42 for forming the collector electrode. The metal layer 45 may include conductive materials like Aluminum (Al), Chrome (Cr), Copper (Cu), Nickel (Ni), Gold (Au) and so on. The back metallization process may include metal deposition, sputtering or other metal film forming process.

The first n-type region 43a, the second n-type region 43b and the third n-type region 43c form the field stop buffer layer 43 of the IGBT. The IGBT devices are required to support different switching characteristics according to applications, therefore a good controllability of the IGBT switching performance is a certainly necessary technology for the semiconductor device 400. Since the recombination of the hole carrier near the field stop layer 43 dominantly determines the switching characteristics, the defect layer 44 is formed around the field stop buffer layer 43 to provide good flexibility on switching performance control in addition to the field stop layer design. The defect layer 44 is effective to improve the switching speed of the IGBT because the accelerating recombination of the injected hole is made by the local life-time control site during switching operation. Therefore, the IGBT device may have the faster switching speed.

The local lifetime control site and the buffer layer can be made by the similar Hydrogen implant process. The only different is the annealing temperature. Accordingly, the field stop buffer layer 43 and the defect layer 44 can be formed by the same process with only the different annealing temperature. The manufacturing process can be simplified to reduce the manufacturing costs. The above description illustrates the back side structure of the semiconductor device 400. The detail manufacturing process to the above structure will be illustrated in the following embodiments.

The present disclosure disclosed herein has been described by means of specific embodiments. However, numerous modifications, variations and enhancements can be made thereto without departing from the spirit and scope of the disclosure set forth in the claims.

What is claimed is:

1. A manufacturing method of forming a semiconductor device, the manufacturing method comprising:
providing a semiconductor substrate, the semiconductor substrate comprising an N-drift layer and the N-drift layer having a front side and a back side;
forming a collector layer in the back side by a P-type implant process and conducting an annealing process to the collector layer;
conducting a first Hydrogen implant process to the back side to form an N-type region and baking the N-type region with a first annealing temperature to form a field stop buffer layer;
conducting a second Hydrogen implant process to the back side to form a lifetime control site and baking the lifetime control site with a second annealing temperature to form a defect layer, the second annealing temperature being lower than the first annealing temperature;
forming a metal layer on the back side by a back metallization process.

2. The manufacturing method of claim 1, wherein the first annealing temperature is over 300° C. and the second annealing temperature is about 100-250° C.

3. The manufacturing method of claim 1, wherein the defect layer is formed in the field stop buffer layer.

4. The manufacturing method of claim 1, wherein the defect layer is formed between the field stop buffer layer and the N-drift layer.

5. The manufacturing method of claim 1, wherein the first Hydrogen implant process implants Hydrogen ions three times to form a first N-type region, a second N-type region and a third N-type region.

6. The manufacturing method of claim 5, wherein the defect layer is formed between the first N-type region and the second N-type region.

7. The manufacturing method of claim 5, wherein the defect layer is formed between the first N-type region and the N-drift layer.

8. The manufacturing method of claim 1, further comprising:
etching the front side to form a trench;
forming a gate oxide layer on the front side and the gate oxide layer covering surface of the trench;
conducting a polysilicon deposition in a trench space and etching back to form a polysilicon layer;
implanting the front side to form a P-well region between two trenches;
implanting the P-well region to form an N-plus layer within the P-well region;
depositing an interlayer dielectric layer to cover the N-plus layer and the polysilicon layer;
etching the interlayer dielectric layer to form an opening, the opening passing through the N-plus layer to expose the P-well region;
implanting the P-well region through the opening to form a P-plus layer;
forming a metal contact layer to cover the opening and the interlayer dielectric layer.

9. The manufacturing method of claim 8, wherein the annealing process is provided after implant process.

10. A semiconductor device comprising:
a semiconductor substrate comprising an N-drift layer, the N-drift layer having a front side and a back side;
a collector layer disposed on the back side and the collector layer comprising a P-type region;
a field stop buffer layer formed between the N-drift layer and the collector layer, the field stop buffer layer comprising an N-type region;
a defect layer formed around boundary of the field stop buffer layer; and
a metal layer disposed on the collector layer;
wherein the field stop buffer layer is formed by a first Hydrogen implant process and a baking process at a first annealing temperature, the defect layer is formed by a second Hydrogen implant process and a baking process at a second annealing temperature, the second annealing temperature is lower than the first annealing temperature.

11. The semiconductor device of claim 10, wherein the first annealing temperature is over 300° C. and the second annealing temperature is about 100-250° C.

12. The semiconductor device of claim 10, wherein the defect layer is disposed in the field stop buffer layer.

13. The semiconductor device of claim 10, wherein the defect layer is disposed between the field stop buffer layer and the N-drift layer.

14. The semiconductor device of claim 10, wherein the field stop buffer layer comprises a first N-type region, a second N-type region and a third N-type region.

15. The semiconductor device of claim 14, wherein the defect layer is disposed between the first N-type region and the second N-type region.

16. The semiconductor device of claim 14, wherein the defect layer is disposed between the first N-type region and the N-drift layer.

17. The semiconductor device of claim 10, further comprising:
a gate oxide layer disposed on a trench of the front side;
a polysilicon layer disposed on the gate oxide layer, the polysilicon layer filling in a trench space;
a P-well region disposed between two trenches;
a P-plus layer and an N-plus layer disposed within the P-well region, the N-plus layer being disposed on the P-plus layer;
an interlayer dielectric layer disposed on the polysilicon layer and the N-plus layer; and
a metal contact layer disposed on the interlayer dielectric layer and the metal contact layer reaching the P-plus layer and the N-plus layer through an opening of the interlayer dielectric layer.
